(19) United States
(12) Patent Application Publication
(10) Pub. No.: US 2024/0337777 A1
(43) Pub. Date: Oct. 10, 2024

(54) MICRO-LENS BASED ON HIGH-REFRACTIVE-INDEX DIELECTRIC SUBSTRATE

(71) Applicant: SOUTH CHINA UNIVERSITY OF TECHNOLOGY, Guangzhou (CN)

(72) Inventors: Zhiyuan LI, Guangzhou (CN); Haoran MO, Guangzhou (CN); Zitao JI, Guangzhou (CN); Yidong ZHENG, Guangzhou (CN)

(73) Assignee: SOUTH CHINA UNIVERSITY OF TECHNOLOGY, Guangzhou (CN)

(21) Appl. No.: 18/748,104

(22) Filed: Jun. 20, 2024

Related U.S. Application Data
(63) Continuation of application No. PCT/CN2022/128464, filed on Oct. 30, 2022.

(30) Foreign Application Priority Data
Dec. 21, 2021 (CN) 202110960195.4

(51) Int. Cl. G02B 3/12; G02B 1/11; H01L 27/146

(52) U.S. Cl. CPC G02B 3/12; G02B 1/11; H01L 27/14627

(57) ABSTRACT

A micro-lens based on a high-refractive-index dielectric substrate, comprising a light-transmitting dielectric substrate. The dielectric substrate has an incident surface for incident light to be incident on, and a wavelength λ of incident light ranges from 2.5 μm-25 μm. The dielectric substrate has an emergent surface and a plano-concave air cavity, and the plano-concave air cavity is formed in the dielectric substrate. One end of the plano-concave air cavity is a planar end facing the incident surface, and the other end is a spherical end having a notch shape and the notch facing the emergent surface, so that the incident light is focused into a focus after passing through the plano-concave air cavity, and thus the full width at half maximum of field intensity at the focus is smaller than the full width at half maximum defined by a Rayleigh diffraction limit formula.

### CROSS-REFERENCE TO RELATED APPLICATION

This application is a continuation of International Patent Application of PCT application serial No. PCT/CN2022/128464, filed on Oct. 30, 2022, which claims the benefit of priority from China Application No. 202110960195.4, filed on Dec. 21, 2021. The entirety of each of the above mentioned patent applications is hereby incorporated by reference herein and made a part of this specification.

### TECHNICAL FIELD

The present invention relates to the technical fields of micro/nano optics and optical imaging, and particularly relates to a micro-lens based on a high-refractive-index dielectric substrate.

### BACKGROUND

Incident light can be diffracted by the finite aperture size of a lens, which results in that light cannot be converged into an infinitesimal spot by the lens, and only an Airy disk with certain energy distribution can be formed at a focus. In general, the process of imaging by any optical instrument can be considered as converting numerous tiny spots on an object into Airy disk patterns and then superimposing them, so that the resulting image cannot accurately describe all details of the object. When a minimum resolvable distance between two Airy disks is that the center of one circular spot coincides with the edge of the other circular spot, this distance is also called Rayleigh criterion. The size of an image point for imaging of the lens is limited by the Rayleigh criterion, namely 0.61 λ/NA, and this formula indicates that light beams are focused into a focused spot with a size above the half-wavelength. Therefore, this impedes further enhancement of a resolution capacity in super-resolution imaging and photoetching. A conventional solution for enhancement of the resolution capacity is to reduce the wavelength or increase the size of the lens.

### SUMMARY

### Technical Solution

The present invention aims at solving at least one of the technical problems above in the prior art to some extent. To this end, an embodiment of the present invention provides a micro-lens based on a high-refractive-index dielectric substrate, and the micro-lens is capable of obtaining an Airy disk that is smaller than a Rayleigh criterion in a defined incident wave band.

The micro-lens based on the high-refractive-index dielectric substrate according to the embodiment of the present invention includes a light-transmitting dielectric substrate. The dielectric substrate has an incident surface for incident light to be incident on, and a wavelength λ of incident light ranges from 2.5 μm-25 μm. The dielectric substrate has an emergent surface and a plano-concave air cavity, and the plano-concave air cavity is provided in the dielectric substrate. One end of the plano-concave air cavity is a planar end facing the incident surface, and another end of the plano-concave air cavity is a spherical end having a notch shape and the notch of spherical end of the plano-concave air cavity faces the emergent surface, such that the incident light is focused into a focus after passing through the plano-concave air cavity, and thus the full width at half maximum of field intensity at the focus is smaller than the full width at half maximum defined by a Rayleigh diffraction limit formula.

In an alternative or preferred embodiment, the wavelength λ of the incident light ranges from 3 μm-5 μm.

In an alternative or preferred embodiment, a distance from a center of the spherical end of the plano-concave air cavity to the emergent surface of the dielectric substrate is defined as L, and L is smaller than a focal length f of the incident light incident from the spherical end of the plano-concave air cavity.

In an alternative or preferred embodiment, a radius of curvature R1 of the spherical end of the plano-concave air cavity ranges from 20 μm-200 μm.

In an alternative or preferred embodiment, the incident surface of the dielectric substrate is plated with an anti-reflection film.

In an alternative or preferred embodiment, the emergent surface of the dielectric substrate is connected to a photodetector.

In an alternative or preferred embodiment, the dielectric substrate is a cylinder, and the incident surface and the emergent surface are located at two end surfaces of the cylinder, respectively.

In an alternative or preferred embodiment, a material of the dielectric substrate is silicon or germanium.

In an alternative or preferred embodiment, a refractive index of the dielectric substrate is greater than 2.0.

In an alternative or preferred embodiment, an imaging law satisfies the following expression:

$$\frac{1}{f} = \frac{n - 1}{n} \frac{1}{{R}_{1}}$$

wherein R₁ is the radius of curvature of the spherical end of the plano-concave air cavity; f is the focal length of the micro-lens based on the high-refractive-index dielectric substrate (calculated by beginning from the plano-concave air cavity); n is the refractive index of the dielectric substrate; and the micro-lens based on the high-refractive-index dielectric substrate with a targeted focal length is obtained by selecting a value of R₁.

### Beneficial Effects

Based on the technical solution above, the embodiments of the present invention have at least the following beneficial effects: in the technical solution above, the plano-concave air cavity is provided in the dielectric substrate; the planar end of the plano-concave air cavity faces the incident surface of the dielectric substrate; the notch of the spherical end of the plano-concave air cavity faces the emergent surface of the dielectric substrate; the incident light in a defined wave band range is incident into the dielectric substrate, and is focused into the focus after passing through the plano-concave air cavity, and the full width at half maximum of the field intensity at the focus is smaller than the full width at half maximum defined by the Rayleigh diffraction limit formula, so that the Airy disk that is smaller than the Rayleigh criterion is achieved, and the existing imaging limit is broken. The micro-lens based on the high-refractive-index dielectric substrate provided by the present invention can be used for optical imaging and detection, and has a wide application prospect in the field of micro/nano optics.

### BRIEF DESCRIPTION OF THE DRAWINGS

The present invention will be further described with reference to the accompanying drawings and embodiments below.

FIG. 1 is a cross-sectional diagram according to an embodiment of the present invention, wherein a cross-sectional line is not drawn.

FIG. 2 is a schematic diagram of optical simulation according to an embodiment of the present invention.

FIG. 3 is a schematic diagram of electric field intensity of a cross section of an imaging focus according to an embodiment of the present invention.

FIG. 4 is a comparison diagram of a simulated curve of imaging focus variations and a theoretical Rayleigh criterion diffraction limit according to an embodiment of the present invention.

FIG. 5 is a schematic diagram of simulation after connecting a mercury cadmium telluride dielectric according to an embodiment of the present invention.

FIG. 6 is a schematic diagram of the electric field intensity of the cross section of the imaging focus after connecting the mercury cadmium telluride dielectric according to an embodiment of the present invention.

FIG. 7 is a schematic diagram of refractive index variations of silicon with wavelength in a 26° C. environment.

### DETAILED DESCRIPTION OF DISCLOSURED EMBODIMENTS

The specific embodiments of the present invention will be described in detail in this part. The preferred embodiments of the present invention are illustrated in the accompanying drawings, and the function of the accompanying drawings is to supplement the description of the specification in the form of text by means of diagrams, so that each technical feature and the overall technical solution of the present invention can be visually and graphically understood, but this cannot be understood as the limitation of the protection scope of the present invention.

In the description of the present invention, it is to be understood that when involving the description of orientations, for embodiment, orientation or positional relationships indicated with respect to “upper”, “lower”, “front”, “rear”, “left”, “right” and the like are orientation or positional relationships shown in the accompanying drawings. The orientation or positional relationships are merely for convenience in describing the present invention and simplifying the description, do not indicate or imply that the device or element referred to must have a particular orientation, be constructed and operated in a particular orientation, and therefore should not be construed as limiting the present invention.

In the description of the present invention, the meaning of “a plurality of” is one or more, and the meaning of “more” is two or more, “greater than”, “less than”, “exceed” and the like are understood as excluding the present number, and “above”, “below”, “in” and the like are understood as including the present number. In case of the description of “first” and “second”, they are provided only for the purpose of distinguishing technical features, and cannot be understood as indicating or implying relative importance or implicitly indicating the number of the technical features indicated or implicitly indicating the precedence of the technical features indicated.

In the description of the present invention, unless the context clearly dictates otherwise, the words “disposed”, “installed”, “connected” and the like should be construed broadly.

A person skilled in the art would be able to rationally determine the specific meaning of the words above in the present invention in combination with the specific contents of the technical solution.

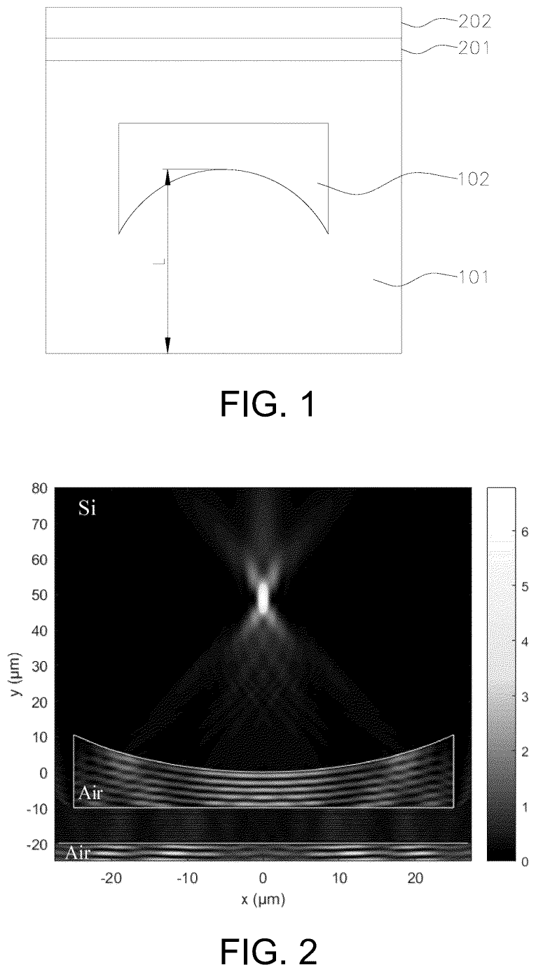

Referring to FIG. 1 to FIG. 7, a micro-lens based on a high-refractive-index dielectric substrate 101 includes the dielectric substrate 101 and a plano-concave air cavity 102.

Wherein the dielectric substrate 101 is light-transmitting, the dielectric substrate 101 selected in this embodiment has a high refractive index, and specifically, the refractive index of the dielectric substrate 101 is greater than 2.0.

The dielectric substrate 101 has an incident surface for incident light to be incident on, and the dielectric substrate 101 has an emergent surface. One end of the plano-concave air cavity 102 is a planar end facing the incident surface, and another end of the plano-concave air cavity 102 is a spherical end having a notch shape, and the notch of the spherical end of the plano-concave air cavity 102 faces the emergent surface, such that the incident light is focused into a focus after passing through the plano-concave air cavity 102. A wavelength λ of the incident light ranges from 2.5 μm-25 μm, and thus the full width at half maximum of field intensity at the focus is smaller than the full width at half maximum defined by a Rayleigh diffraction limit formula. More specifically, the wavelength λ of the incident light ranges from 3 μm-5 μm, and thus the full width at half maximum of the field intensity at the focus can be more desirable.

In one embodiment, the dielectric substrate 101 is a cylinder, and the incident surface and the emergent surface are located at two end surfaces of the cylinder, respectively. The incident surface of the dielectric substrate 101 is plated with an anti-reflection film, such that the amount of incident light can be increased. The specific number of layers of the anti-reflection film depends on the actual application scenario required. In this embodiment, the anti-reflection film includes a first anti-reflection film 201 and a second anti-reflection film 202. In addition, the emergent surface of the dielectric substrate 101 is connected to a photodetector.

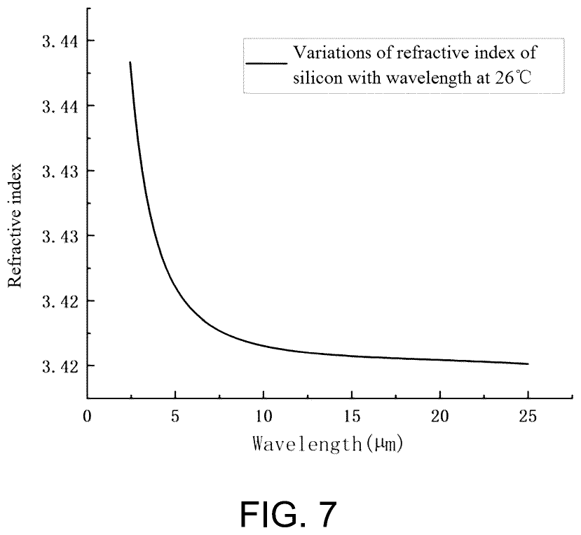

A material of the dielectric substrate 101 is silicon or germanium. Referring to FIG. 7, in the wave band of the wavelength λ of the incident light ranges from 2.5 μm-25 μm, the refractive index of silicon is greater than 3.41, which is a relatively large value, so that silicon can be selected as the substrate material of the micro-lens in this wave band.

At a temperature of 26° C. and a wavelength of 2.5 μm-25 μm, a dispersion formula of silicon is as follows:

$$n = 3.41983 + \frac{0.159906}{{λ}^{2} - 0.028} - 0.123109 {( \frac{1}{{λ}^{2} - 0.028} )}^{2} + 1.26878 \times {10}^{- 6} {λ}^{2} - 1.95104 \times {10}^{- 9} {λ}^{4}$$

In this embodiment, silicon is used as the material of the dielectric substrate 101, and at a wavelength band of 3 μm-5 μm, silicon has good light transmittance and a high refractive index, and a specific imaging law satisfies the following expression:

$$\frac{1}{f} = \frac{{n}_{Si} - 1}{{n}_{Si}} \frac{1}{{R}_{1}}$$

wherein R1 is a radius of curvature of the spherical end of the plano-concave air cavity 102, and the radius of curvature R1 of the spherical end of the plano-concave air cavity 102 ranges from 20 μm-200 μm.
f is a focal length of the micro-lens based on the high-refractive-index dielectric substrate 101 (calculated by beginning from the plano-concave air cavity 102).
nₛᵢ is a refractive index of the dielectric substrate 101.

The micro-lens based on the high-refractive-index dielectric substrate 101 with a targeted focal length is obtained by selecting a value of R1.

It is understandable that from the expression of the imaging law above, after determining the parameter of the targeted focal length f, an appropriate value of R1 can be determined to manufacture the micro-lens with the targeted focal length.

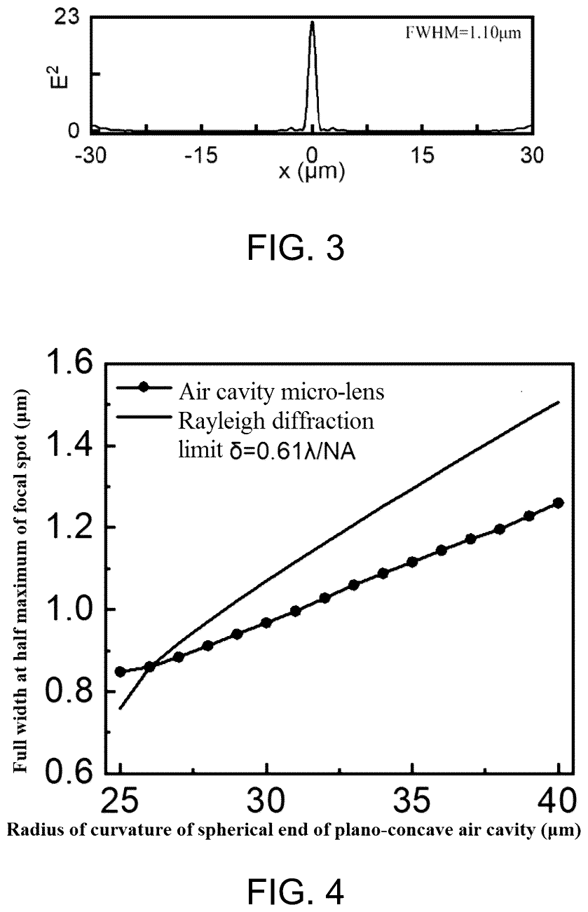

FIG. 2 is a schematic diagram of optical simulation, wherein the dielectric substrate 101 is silicon, and the incident light is normally incident on the micro-lens, at this moment, the emergent surface of the dielectric substrate 101 is not connected to the photodetector, and specifically is not connected to a mercury cadmium telluride photoelectric detection assembly. The wavelength of the incident light is 4 μm, and the incident light can form a focus after passing through the spherical end of the plano-concave air cavity 102 of the micro-lens. FIG. 3 is a schematic diagram of electric field intensity of a cross section of an imaging focus. In addition, by adjusting the radius of curvature of the spherical end of the plano-concave air cavity 102 in the micro-lens, the full width at half maximum of field intensity at the focus is smaller than the full width at half maximum defined by the Rayleigh diffraction limit formula. In the case of incident light in a wave band range of 3 μm-5 μm, variations of the full width at half maximum of the focus and variations of a Rayleigh diffraction resolution limit are shown in FIG. 4. FIG. 4 shows calculated results corresponding to different radii of curvature of a curved surface in the case of the incident light with a wavelength of 4 μm. It can be seen that in the set operating wavelength range, by changing parameters of the micro-lens, the effect that the full width at half maximum of the focal length smaller than the Rayleigh diffraction limit can be achieved.

In one embodiment, a distance from a center of the spherical end of the plano-concave air cavity 102 to the emergent surface of the dielectric substrate 101 is defined as L, and L is smaller than a focal length f of the incident light incident from the spherical end of the plano-concave air cavity 102. It is understandable that the focal length of the micro-lens based on the high-refractive-index dielectric substrate 101 does not fall into the dielectric substrate 101.

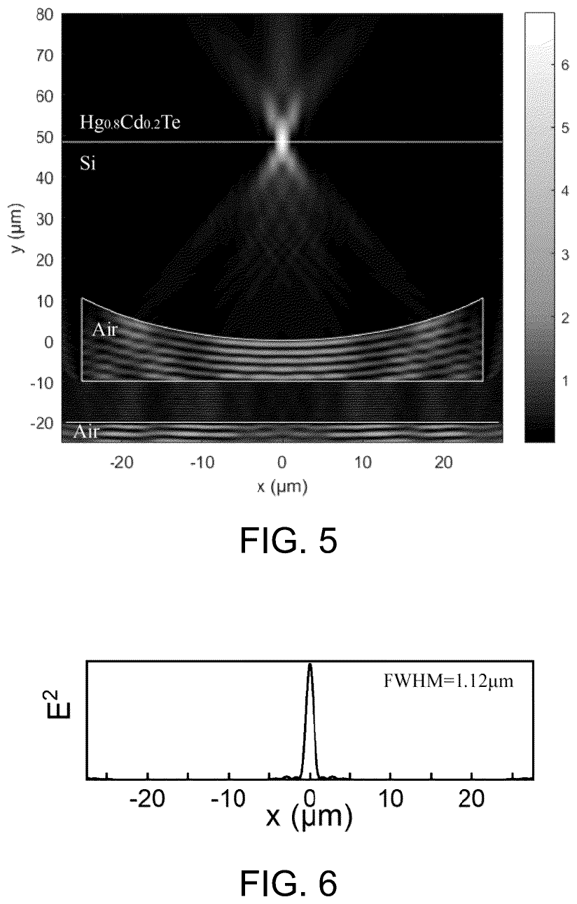

In another embodiment, the emergent surface of the dielectric substrate 101 is connected to a photodetector, and specifically is connected to a mercury cadmium telluride photoelectric detection assembly including assemblies such as a mercury cadmium telluride dielectric and a CCD camera. The dielectric substrate 101 is silicon, and the incident light is normally incident on the micro-lens. The micro-lens based on the silicon substrate constitutes a set of single-lens imaging system which can be used for 3 μm-5 μm optical imaging and detection. The refractive index of mercury cadmium telluride is closely related to a material composition thereof. It is assumed that under the condition that the optical imaging and detection system operates at room temperature, when the material composition of the mercury cadmium telluride is Hg0.8Cd0.2Te, the refractive index of the mercury cadmium telluride dielectric is substantially matched with that of the silicon dielectric. FIG. 5 is a diagram of simulated field intensity after the emergent surface is connected to the mercury cadmium telluride dielectric. FIG. 6 is a schematic diagram of the electric field intensity of the cross section of the imaging focus after connecting the mercury cadmium telluride dielectric. It can be seen that when the mercury cadmium telluride dielectric is connected later, an imaging effect does not vary greatly, and the small diffraction limit can still be achieved by the size of a focal spot. An imaged image can be output into a device by the CCD camera connected later.

Although the embodiments of the present invention have been described in detail with reference to the accompanying drawings, the present invention is not limited to the examples above. Many variations can be made without departing from the spirit of the present invention in the scope of knowledge of those ordinarily skilled in the art.

What is claimed is:

1. A micro-lens based on a high-refractive-index dielectric substrate, comprising a light-transmitting dielectric substrate, wherein the dielectric substrate has an incident surface for incident light to be incident on, a wavelength λ of the incident light ranges from 2.5 μm-25 μm, and the dielectric substrate has an emergent surface; and
a plano-concave air cavity, wherein the plano-concave air cavity is formed in the dielectric substrate, one end of the plano-concave air cavity is a planar end facing the incident surface, another end of the plano-concave air cavity is a spherical end having a notch shape, the notch of spherical end of the plano-concave air cavity faces the emergent surface, such that the incident light is focused into a focus after passing through the plano-concave air cavity, and thus a full width at half maximum of field intensity at the focus is smaller than a full width at half maximum defined by a Rayleigh diffraction limit formula.

2. The micro-lens based on the high-refractive-index dielectric substrate according to claim 1, wherein the wavelength λ of the incident light ranges from 3 μm-5 μm.

3. The micro-lens based on the high-refractive-index dielectric substrate according to claim 1, wherein a radius of curvature R1 of the spherical end of the plano-concave air cavity ranges from 20 μm-200 μm.

4. The micro-lens based on the high-refractive-index dielectric substrate according to claim 1, wherein a distance from a center of the spherical end of the plano-concave air cavity to the emergent surface of the dielectric substrate is defined as L, and L is smaller than a focal length f of the incident light incident from the spherical end of the plano-concave air cavity.

5. The micro-lens based on the high-refractive-index dielectric substrate according to claim 1, wherein the incident surface of the dielectric substrate is plated with an anti-reflection film.

6. The micro-lens based on the high-refractive-index dielectric substrate according to claim 5, wherein the emergent surface of the dielectric substrate is connected to a photodetector.

7. The micro-lens based on the high-refractive-index dielectric substrate according to claim 6, wherein the dielectric substrate is a cylinder, and the incident surface and the emergent surface are located at two end surfaces of the cylinder, respectively.

8. The micro-lens based on the high-refractive-index dielectric substrate according to claim 1, wherein a refractive index of the dielectric substrate is greater than 2.0.

9. The micro-lens based on the high-refractive-index dielectric substrate according to claim 8, wherein a material of the dielectric substrate is silicon or germanium.

10. The micro-lens based on the high-refractive-index dielectric substrate according to claim 8, wherein an imaging law satisfies the following expression:
$$\frac{1}{f} = \frac{n - 1}{n} \frac{1}{{R}_{1}}$$
wherein R₁ is the radius of curvature of the spherical end of the plano-concave air cavity; f is the focal length of the micro-lens based on the high-refractive-index dielectric substrate calculated by beginning from the plano-concave air cavity; n is the refractive index of the dielectric substrate; and the micro-lens based on the high-refractive-index dielectric substrate with a targeted focal length is obtained by selecting a value of R1.
